(19) United States
(12) Patent Application Publication
(10) Pub. No.: US 2010/0136785 A1
(43) Pub. Date: Jun. 3, 2010

(54) DIRECT PATTERNING METHOD FOR MANUFACTURING A METAL LAYER OF A SEMICONDUCTOR DEVICE

(75) Inventors: Ming-Nan HSIAO, Taichung City (TW); Shin-Chuang Chiang, Taipei City (TW); Bor-Chuan Chuang, Tai Nan Hsien (TW)

Correspondence Address: RABIN & Berdo, PC, 1101 14TH STREET, NW, SUITE 500, WASHINGTON, DC, 20005, US

(73) Assignees: TAIWAN TFT LCD ASSOCIATION, Hsinchu (TW); CHUNGHWA PICTURE TUBES, LTD., Padeh City (TW); AU OPTRONICS CORP., Hain-Chu (TW); QUANTA DISPLAY INC., Tao Yuan Shien (TW); HANNSTAR DISPLAY CORP, Taipei (TW); CHI MEI OPTOELECTRONICS CORP., Tainan County (TW); INDUSTRIAL TECHNOLOGY RESEARCH INSTITUTE, Hsinchu (TW); TOPOLY OPTOELECTRONICS CORP., Chu-Nan (TW)

(21) Appl. No.: 12/699,429

(22) Filed: Feb. 3, 2010

Related U.S. Application Data
(62) Division of application No. 11/441,095, filed on May 26, 2006.

(30) Foreign Application Priority Data
Dec. 20, 2005 (TW) 94145303

(51) Int. Cl. H01L 21/768

(52) U.S. Cl. 438/669; 977/777; 257/E21.582

(57) ABSTRACT

A direct patterning method for manufacturing a metal layer of a semiconductor device is provided. The claimed method reduces the materials and hours required by prior methods such as the thin film depositing method for a substrate, and the photolithographic method for manufacturing a transistor.

The preferred embodiment of the present invention comprises a step of defining the pattern of the seeder material and a step of selectively thin film deposition. The direct patterned technology for the seeder and a chemical bath deposition (CBD) are utilized to provide the thin film growing method with non-vacuum and selective deposition. The object of the invention is applied to produce the wire or electrode, within the semiconductor device, or to deposit and manufacture the thin film in the large-area transistor array or a reflective layer.

### CROSS-REFERENCE TO RELATED APPLICATION

This application is a divisional of copending application Ser. No. 11/441,095, filed May 26, 2006, and the right of priority of parent application is and was claimed under 35 USC §119 of Taiwanese Application No. 94145303, filed Dec. 20, 2005, the entire disclosure of which is incorporated herein by reference.

### BACKGROUND OF THE INVENTION

1. Field of the Invention

The present invention relates to a direct patterning method for manufacturing a metal thin film of a semiconductor device, and more particularly, to a direct patterned technology for the seeder and a chemical bath deposition (CBD) applied on a thin film deposition method provided for a semiconductor device.

2. Description of Related Art

In the conventional art, the methods of a thin film deposition and photolithography have been adopted as the method for manufacturing the thin-film transistor (TFT) device for decades. Since the substrate size has been getting larger in recent years, the amount of material needed for the above-mentioned manufacturing method, such as the thin film deposition and photolithography, has increased simultaneously. Furthermore, the cost of relevant equipments has also increased. This has placed a larger financial burden upon manufacturers using the method. Therefore, some prior arts have been provided to replace the conventional manufacturing method for solving the technical bottlenecks thereof.

For example, U.S. Pat. No. 6,329,226 discloses a method for fabricating a thin-film transistor. The method features a self-assembly monolayer (SAM) defined by the method of microcontact printing used as an etching mask of a silver electrode, wherein the silver layer is deposited with conventional electroless plating. Accordingly, various parts of the TFT can be formed by performing the microcontact printing process, such as a stamping process. Thus, a good deal of electrodes can be made by using the stamping process, which defined the etching mask in a printing process and replaced the method of photolithography. However, the above-mentioned method is still adopted for full-sized deposition in tandem with the etching process.

Please refer to U.S. Pat. No. 6,521,489, which provides preferred methods for producing electrical circuit elements used to control an electronic display. The structure shown in FIG. 2, includes a gate 30 formed on the substrate clothed by a dielectric layer 60. Next, a semiconductor layer 70 is formed above the dielectric layer 60, and a drain 20 and a source 10 are formed by way of deposition. Particularly, the methods of printing and depositing can be introduced into forming the gate 30 of the transistor. U.S. Pat. No. 6,413,790, also shows a similar method herewith.

Furthermore, the above-mentioned manufacturing method is described in FIG. 1, which shows a schematic diagram of the ink-jet printing method for manufacturing a TFT. A printing device 101 shown in the figure prints the ink-like (103) material onto a rough surface in a precise manner. For example, a thin film 103′ is formed thereby on a semiconductor material 105 positioned on a substrate 107. Particularly, the technology has been adopted to ink-jet print a nano-material to form a nano-scale thin film precisely, such as the gate, drain and the source electrodes of a transistor.

The critical technology uses a method of mechanically or non-mechanically contacting to define a pattern directly. The means of contacting include micro-contact printing, ink-jet printing, screen printing, relief printing, and gravure printing implemented by a skilled technician. Moreover, the material to be printed can be a conductive paste, a gel-suspension solution, or a conductive polymer. The material also needs to add surfactant and a binder if the method of mechanically contacting is used to define the pattern, so as to adjust the viscosity and the nano-particle dispersing. Therefore, the characteristic of the thin film is affected by the additive. The resistivity of the metal thin film is higher while the dielectric properties of the dielectric material can be a combination of various materials.

In view of the high cost caused by the procedure of photolithography and vacuum-coating, and that the method of ink-jet printing degrades the property of the thin film, the present invention provides an alternative technology that not only decreases costs, but also raises the efficiency of manufacturing display panels.

### SUMMARY OF THE DISCLOSURE

The present invention relates to a direct patterning method for manufacturing a metal layer of a semiconductor device. The method combines the direct patterning method of seeder and the process of chemical bath deposition to provide a process for depositing a thin film that doesn't require vacuuming or selective deposition conditions. The method is applied to depositing, producing a large-area TFT array or a large-area functional thin film, and the metal thin film is utilized for a specific semiconductor structure, such as can be found in a conductive wire, an electrode, a reflective layer, or the like.

The claimed method is applied to a semiconductor device or formed on a substrate. The first embodiment of the present invention includes a first step of preparing a fundamental structure such as a substrate or a semi-finished semiconductor product. Next, the method further includes a step of defining a pattern on the fundamental structure using a mask, and then a step of dipping the fundamental structure with the defined pattern into a solution so as to form a seeding layer. Next, the method includes a step of removing the mask, and a step of chemical bath deposition (CBD), i.e. dipping the patterned seeder into a CBD solution. Finally, a metal film is formed. More particularly, the preferred embodiment of the metal film is the metal (silver) with high-reflectivity and low-resistivity.

The second embodiment of the direct patterning method for manufacturing a metal layer of a semiconductor device includes a first step of preparing a fundamental structure. Next, a step of coating a precursor on the fundamental structure and a step of forming a pattern using a step of a direct patterning method are performed. At the same time, the precursor's surface is activated so as to form a seeding layer. Afterward, the method includes a step of removing a non-activating material on the fundamental structure and a step of chemical bath deposition, wherein the step of dipping the seeder means into a CBD solution is performed. At last, a metal film is formed. The preferred embodiment of the mentioned metal film uses a metal (preferably silver) with high-reflectivity and low-resistivity. Furthermore, the precursor can be one or a combination of various organometallic compounds, such as tin, platinum, palladium, and silver. The direct patterning method can be implemented via laser, a single-wavelength ray, or a hybrid ray with multiple wavelengths. Next, the third embodiment of the direct patterning method for manufacturing a metal layer of a semiconductor device comprises a first step of preparing a fundamental structure. Next, a step of coating a photosensitive precursor onto the fundamental structure is performed. Afterward, the photosensitive precursor is exposed using a light source with a single-wavelength ray or a hybrid ray with multiple wavelengths so as to form a pattern. Next, a seeder is formed and activated by heating the patterned precursor. Then the seeder is dipped into a CBD solution, and a step of chemical bath deposition is performed thereon so as to form a metal film. The preferred embodiment of the photosensitive precursor can be one or the combination of various organometallic compounds, such as tin, platinum, palladium, or silver. Particularly, the preferred embodiment of the metal film uses silver which has high-reflectivity and low-resistivity properties.

Furthermore, the fourth embodiment of the present invention comprises the steps of firstly preparing a fundamental structure, such as a substrate or a semi-finished semiconductor product. Next, of forming a precursor of a direct patterning seeding layer on the fundamental structure via a step of ink-jet printing, micro-contact printing, or laser-electrostatic absorption. After that, the seeder is formed by heating and activating the patterned precursor. Next, the seeder means is positioned in a CBD solution, and a step of chemical bath deposition is performed thereon so as to form a metal film. The preferred embodiment of the above-mentioned metal film uses silver which has the properties of high-reflectivity and low-resistivity.

According to the above embodiments, the preferred embodiment of the method of direct patterned includes the following steps:
1. A mask is utilized to define a pattern on the fundamental structure of the substrate or a semi-finished semiconductor product, wherein the step of defining the pattern further includes a step of removing the un-activated region using a specific solution; or
2. The direct patterning method is implemented by a laser; or
3. The precursor of the seeder is patterned on the fundamental structure like a substrate or a semi-finished semiconductor product via contact printing with heat; or
4. A suitable light source is used to radiate the fundamental structure, such as the substrate or the semi-finished semiconductor product, to selectively define the pattern of the precursor of the seeder; or
5. A method of ink-jet printing is used to directly define the pattern of the precursor of the seeder; or
6. A method of microcontact printing is used to directly define the pattern of the precursor of the seeder on the fundamental structure such as the substrate or the semi-finished semiconductor product; or
7. A method of laser-electrostatic absorption directly defines the pattern of the precursor of the seeder on the fundamental structure.

### BRIEF DESCRIPTION OF DRAWINGS

The present invention will be more readily understood by referring to the following detailed description in conjunction with the accompanying drawings, in which:

FIG. 1 is a schema of manufacturing a thin film transistor using the ink-jet printing technology of the prior art;

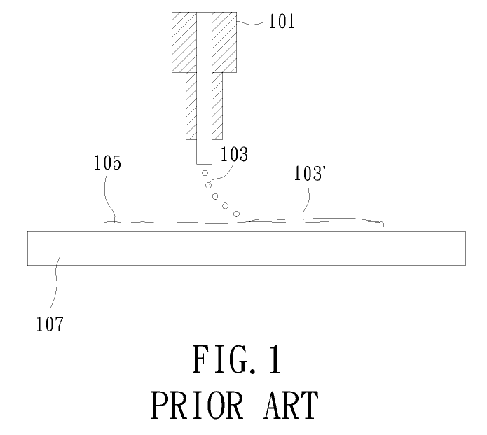

FIG. 2 is a schematic diagram of the prior transistor's structure;

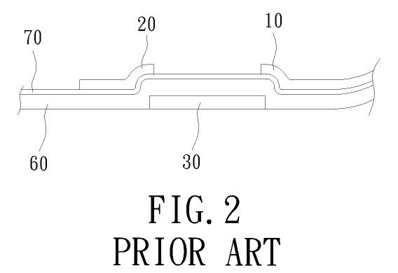

FIG. 3 shows a flow chart for the direct patterning method for manufacturing a metal layer of the first embodiment of the present invention;

FIG. 4 shows a flow chart for the direct patterning method for manufacturing a metal layer of the second embodiment of the present invention;

FIG. 5 shows a flow chart for the direct patterning method for manufacturing a metal layer of the third embodiment of the present invention;

FIG. 6 shows a flow chart for the direct patterning method for manufacturing a metal layer of the fourth embodiment of the present invention;

FIG. 7 shows a patterned silver thin film manufactured by CBD described in the first embodiment of the present invention;

FIG. 8 shows the reflectivity of the deposited silver thin film for various wavelengths measured by a color-filter colorimeter according to various wavelengths.

### DETAILED DESCRIPTION OF THE PREFERRED EMBODIMENTS

To understand the technology, means and functions adopted in the present invention further reference are made to the following detailed description and attached drawings. The invention shall be readily understood deeply and concretely from the purpose, characteristics and specification. Nevertheless, the present invention is not limited to the attached drawings and embodiments in following description.

The present invention relates a direct patterning method for manufacturing a metal layer of a semiconductor device. The claimed method employs several seeding materials, and then adopts a method of chemical bath deposition (CBD) to manufacture a metal layer of the semiconductor device. In an exemplary embodiment, the metal layer is used as the thin metal film of a reflective layer in a TFT (thin film transistor) array, or a wire and electrode formed in the semiconductor device. More particularly, the mentioned manufacturing procedure integrates the direct patterning method of the seeder and the CBD technology so as to provide a non-vacuum and selective deposition manufacturing method of the thin film structure. The claimed method can be substituted for the conventional TFT manufacturing method.

The direct patterning method of the present invention can be used for manufacturing a large-area transistor-array or a large-area functional TFT array. In addition to forming the conducting layer of the transistor, which is the primary use of the method, an optical-reflective film used in a transflective LCD can also make use of the claimed method as well.

The direction pattern method for manufacturing the metal layer of the semiconductor device is provided for the manufacturing method of the semiconductor device, a TFT, a functional thin film array, or a reflective thin film, a metal thin film (such as a wire, an electrode, or the like) of transflective LCD.

Since the claimed method is applied to manufacturing the metal thin film of the semiconductor device, the metal thin film is not necessarily formed on a substrate. If the substrate is required, then the substrate can be an organic dielectric material such as metal and polyimide, or an inorganic dielectric material such as glass, silicide and ceramics, or a flexible substrate.

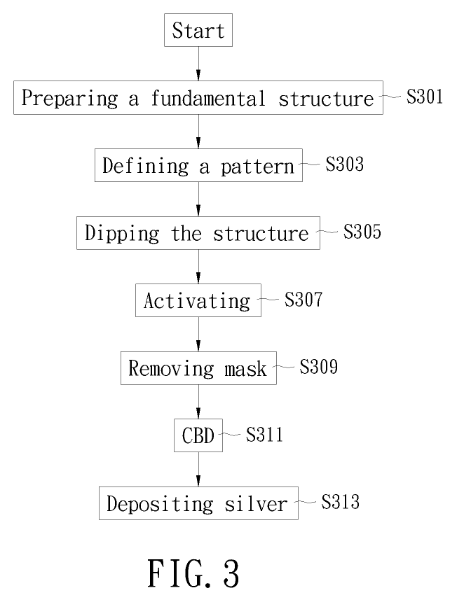

The first embodiment of the present invention relates to the direct patterning method of the metal layer shown in FIG. 3. In the first S301, a fundamental structure, such as a substrate or a semi-finished semiconductor product, is prepared. Next, a photoresist or other equivalent masking means is used to define a pattern on the fundamental structure according to the requirements in practice (S303). The mentioned defined pattern can be the positioning of the electrode, the wire or the like of the transistor. Afterward, the patterned fundamental structure is dipped into a solution so as to form a seeder, wherein the solution includes the composition of the metallic material of the seeder (S305). Next, the surface of the patterned fundamental structure is activated in S307. The masking means is removed in the next S309, and a step of chemical bath deposition (CBD) is performed, i.e. dipping the patterned seeder structure into a CBD solution after removing the masking means in order to develop the thin film thereof (S311). Finally, a metal film is formed after the selective deposition is performed on the seeder structure in the CBD step (S313). The preferred embodiment of the composition of metal film uses gold, silver, aluminum, copper or its alloy. Any one of these materials may be used as the solution used in the CBD process.

The above-mentioned steps of metal thin film development are applied to produce a metallic wire or optical-reflective thin film for a display device or other semiconductor device. The preferred embodiment of the metallic thin film uses silver, which has the properties of high-reflectivity and low-resistivity. So the composition of CBD solution also has silver in order to develop the related metallic thin film. The mentioned CBD process used to develop the metallic thin film on the patterned seeder is a low-cost thin film developing method for forming the thin film having various types or materials.

To sum up the first embodiment of the present invention, the direct patterned technology used on the seeder (or catalytic layer) incorporates the CBD process to develop the single or multiple thin film transistor, so the CBD process can selectively deposit metallic compound on the patterned seeding layer (or catalytic layer). Finally, an excellent-quality thin film structure is obtained after precise control of the material composition and a suitable aftertreatment. Furthermore, the seeder or the catalytic layer can be a buffer layer of a multiple-layer deposition in another embodiment, so that the most amount of residue is prevented from affecting the interface properties. Otherwise the residue will detrimentally affect the interface properties between the layers of the thin film structure.

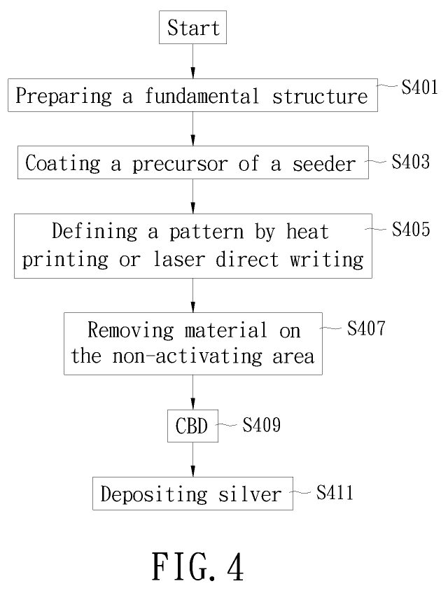

The second embodiment of the direct patterning method for manufacturing a metal thin film of a substrate or a semiconductor device is shown in the flow chart in FIG. 4.

In the beginning, a fundamental structure, such as the substrate or the semiconductor device, is prepared (S401). Next, a precursor of a seeder is coated on the fundamental structure in S403, i.e. the step forms the film of the precursor having the composition of the seeder on the substrate or the semiconductor device. The process of coating can be a step of spin-coating, dipping, ink-jet printing, screen printing, transfer printing, or the like. Moreover, the mentioned precursor can be one or a combination of the organic metal compounds, such as tin, platinum, palladium, or silver.

Afterward, a pattern is formed by a step of heating and transfer printing, or direct writing using a light source. The preferred embodiment of the light source can be laser, a single-wavelength ray or a hybrid ray with multiple-wavelength. The surface of the precursor is activated during the process of heating or the light source radiating, thus a seeder is developed (S405). Whereby, the wire(s), electrode(s) or the structure of reflective layer(s) of the semiconductor device is formed directly. Particularly, in addition to the above-mentioned laser, single-wavelength ray or hybrid ray, a method of mechanically or non-mechanically contacting can be used to selectively activate the patterned precursor of the seeder is order to promote the adhesion in the process of CBD. Wherein, the mentioned process of light source radiating for forming the pattern is a non-mechanically-selectively-contact activating process, and activating process with the heating and transfer printing is a mechanically-contact activating process.

Then, the method goes to remove the material on the non-activated area of the surface of the seeder (S407). The seeder structure after the removing process is positioned in a CBD solution (S409). The chemical bath deposition process is performed on the seeder structure, and then the metal thin film is formed by the selective deposition (S411). The preferred embodiment of the formed metal is silver with high-reflectivity and low-resistivity.

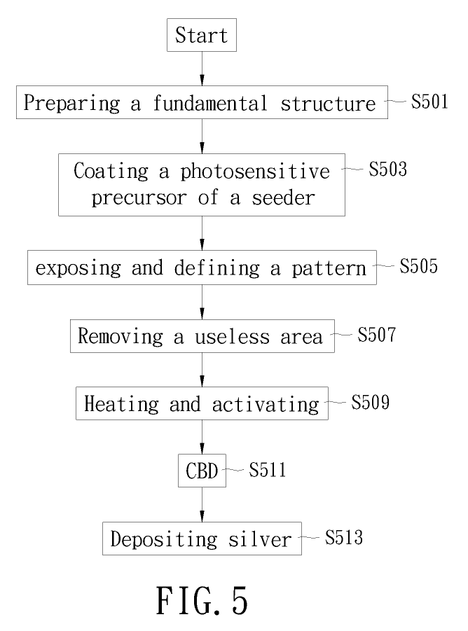

FIG. 5 shows the third embodiment of the present invention. The fundamental structure such as a substrate or a semiconductor device is prepared in the first S501. Next, the precursor for a photosensitive seeder is coated on the fundamental structure (S503). Since the precursor is a photosensitive material, a light source can be used to expose the surface thereon so as to define and form a pattern (S505). The light source can be an ultraviolet light having a single-wavelength or multiple wavelengths, a laser or other sources corresponding to the photosensitive material. After that, a specific solution is used to remove the unused area thereon after exposure (S507). Next, a patterned seeding layer is formed by heating in order to activate the area after removing the aforementioned unused area through exposure (S509). Then the seeder structure is dipped into a CBD solution, and a step of chemical bath deposition is performed thereon (S511). Next, a metal thin film is formed by selectively depositing the seeder structure using CBD process (S513). Particularly, the preferred embodiment of the metal thin film uses sliver, which has high-reflectivity and low-resistivity, and the preferred embodiment of the photosensitive precursor can be one of, or the combination of, various organometallic compounds, such as tin, platinum, palladium, or silver.

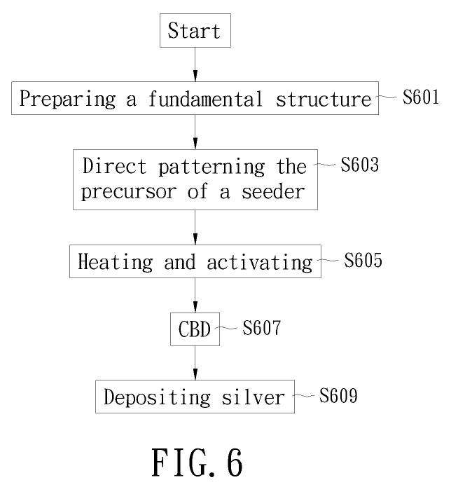

The flow chart of the fourth embodiment of the present invention is shown in FIG. 6. Initially, a fundamental structure is prepared, and the claimed method thereof is performed on the structure, such as a substrate or a semi-finished semiconductor product (S601). Next, a precursor of a seeder is formed on the fundamental structure via a step of direct patterned process (S603). The 5603 directly defines the position(s) of the wire(s), electrode(s) or reflective layer(s) of a semiconductor device, and the direct patterned process can be a step of ink-jet printing, which is used to directly jet the material having the composition of the precursor of the seeder onto the fundamental structure. Other equivalent methods, such as micro-contact printing or laser-electrostatic absorption (consisting of tin, platinum, palladium, or silver), can also be used to perform the direct patterned process.

Next, the seeder is formed by heating the mentioned patterned precursor so that it is activated in 5605. Next, the seeder structure is positioned in a CBD solution, and a step of chemical bath deposition is performed thereon (S607). Finally, a metal thin film is formed via a selectively depositing process (S609). The CBD solution has a metal compound required for the metal thin film to be formed, and the preferred embodiment of the above-mentioned metal thin film uses silver, which has the properties of high-reflectivity and low-resistivity.

In the aforementioned embodiments, the precursor consists of a material that can be one or a combination of various organometallic compounds, such as tin, platinum, palladium, or silver. Moreover, the nano-powder can also be tin, platinum, palladium, or silver. The mentioned activation process is performed to promote the adhesion during the CBD process.

According to the above embodiments, the preferred embodiment of the method of direct patterned can be briefly described as:
1. A mask is utilized to define a pattern on the fundamental structure of the substrate or a semi-finished semiconductor product, wherein the step of defining the pattern further includes a step of removing the un-activated region via a specific solution; or
2. The direct patterning method is implemented by a laser; or
3. The precursor of the seeder is patterned on the fundamental structure like a substrate or a semi-finished semiconductor product by way of contact printing with heat; or
4. A suitable light source is used to radiate the fundamental structure, such as the substrate or the semi-finished semiconductor product, to selectively define the pattern of the precursor of the seeder; or
5. A method of ink-jet printing is used to directly define the pattern of the precursor of the seeder; or
6. A method of microcontact printing is used to directly define the pattern of the precursor of the seeder on the fundamental structure such as a substrate or a semi-finished semiconductor product; or
7. A method of laser-electrostatic absorption directly defines the pattern of the precursor of the seeder on the fundamental structure.

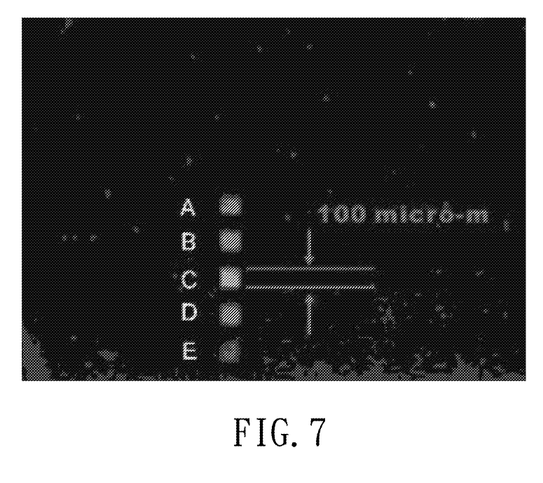

Below a plurality of experimental results is shown to illustrate the embodiments of the direct patterning method of the metal layer of the present invention:
1. In the spin-coating process of the embodiment of the present invention, a p-xylene solution having the composition of a seeder (or catalyst) precursor (Stannous octoate) is coated on a glass substrate. After a process of spin-coating, the seeder is heated and baked. Next, the seeder is selectively activated and patterned by radiating an excimer laser through a mask. The glass substrate is radiated from above by the laser, thereby the non-activated area dipped in the p-xylene solution is removed. Then, the seeder is processed using the chemical bath deposition (CBD), which is silver, and the required patterned silver thin film is formed after a suitable treatment period. Please refer to FIG. 7. The numeral marks A, B, C, D and E show the patterned silver thin films after the CBD process shown in the exemplary embodiment of FIG. 3. The thickness of the films of the present example is 150 nm.
2. A spin-coating process is used to coat a p-xylene solution having the composition of the seeder precursor on a glass substrate. After the seeder is heated and baked after the spin-coating process, a hot metal film is used to selectively activate the seeder. Then the non-activated area on the seeder dipped in the p-xylene solution is removed after activation. After that, the seeder is processed using the CBD process, wherein the CBD solution has silver ions. Finally, a patterned silver thin film is formed after a suitable treatment period.

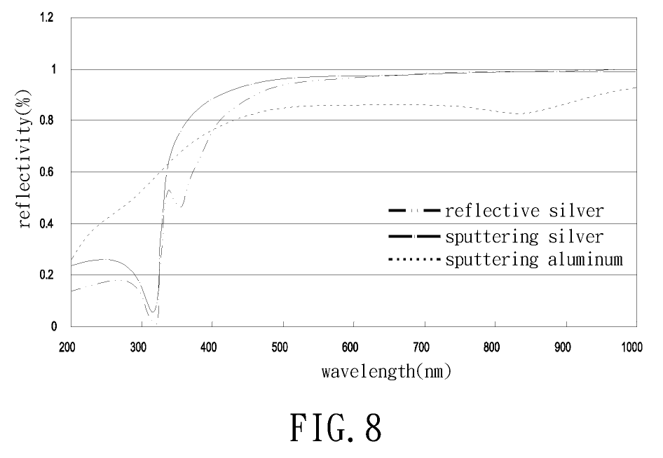

FIG. 8 shows the curves of the reflectivities of the deposited silver thin film, sputtered silver (Ag), and sputtered aluminum (Al) under different conditions with several different wavelengths as measured by a color filter colorimeter (SCI, FILMTEX 3000 model). Obviously, the average of the measured silver reflectivity in the visible-light region is higher than the reflectivity of the sputtered aluminum and slightly lower than the reflectivity of the sputtered silver. Therefore, the deposited silver of the present invention can be applied to the reflective layer of a total-reflection display or a partial-reflection (such as a transflective display) display.

To sum up, the present invention relates to a direct patterning method that can be used to produce a metal layer of a semiconductor device. The claimed method involves the steps of preparing a substrate, patterning and activating, and further involves the CBD process and forming a metal thin film by selective deposition. The present invention is particularly applied to the depositing and manufacturing method for the large-area TFT array.

The many features and advantages of the present invention are apparent from the written description above and it is intended by the appended claims to cover all. Furthermore, since numerous modifications and changes will readily occur to those skilled in the art, it is not desired to limit the invention to the exact construction and operation as illustrated and described. Hence, all suitable modifications and equivalents may be resorted to as falling within the scope of the invention.

What is claimed is:

1. A direct patterning method for manufacturing a metal layer, comprising:
preparing a fundamental structure;
forming a precursor of a direct patterned seeder on the fundamental structure;
forming the seeder by heating the patterned precursor so that the seeder is activated;
performing a step of chemical bath deposition, wherein the seeder is dipped into a CBD solution; and
forming a metal film.

2. The method of claim 1, wherein the step of forming the precursor of the direct patterned seeder is achieved by directly printing the precursor material on the fundamental structure via ink-jet printing.

3. The method of claim 1, wherein the step of forming the precursor of the direct patterned seeder is achieved by micro-contact printing.

4. The method of claim 1, wherein the step of forming the precursor of the direct patterned seeder is achieved by laser-electrostatic absorption of nano-powder.

5. The method of claim 1, wherein the precursor is a nano-powder that consists of tin, platinum, palladium, silver, or alloys of the metals.

6. The method of claim 1, wherein the precursor is one or a combination of the organometallic compounds including tin, platinum, palladium, silver, or alloys of the metals.

7. The method of claim 1, wherein the metal film is silver.

8. The method of claim 1, wherein the metal film is an optical-reflective film.

9. The method of claim 1, wherein the metal film is a metal with high-reflectivity and low-resistivity.

10. The method of claim 1, wherein the CBD solution includes one of the components that exists in the metal film.

11. The method of claim 1, wherein the direct patterning method for manufacturing the metal layer is applied to a semiconductor device.

12. The method of claim 1, wherein the direct patterning method for manufacturing the metal layer is applied upon a substrate.
